(19) United States
(12) Patent Application Publication
(10) Pub. No.: US 2026/0220346 A1
(43) Pub. Date: Jul. 30, 2026

(54) LIGHT INCREMENTAL FLOW FOR QUALITY-OF-RESULT RESILIENCE

(71) Applicants: Advanced Micro Devices, Inc., Santa Clara, CA (US); Xilinx, Inc., San Jose, CA (US)

(72) Inventors: V. Santhosh Padala, Hyderabad (IN); Megha Sangtani, Hyderabad (IN); Pawan Kumar Singh, Lucknow (IN); Mohit Sharma, Jaipur (IN); Shefali Mishra, Hyderabad (IN); Kumari Kajal, Jamshedpur (IN); Vivek Kumar, Pipehara (IN)

(73) Assignees: Advanced Micro Devices, Inc., Santa Clara, CA (US); Xilinx, Inc., San Jose, CA (US)

(21) Appl. No.: 19/040,538

(22) Filed: Jan. 29, 2025

(51) Int. Cl. G06F 30/392; G06F 30/394

(52) U.S. Cl. CPC G06F 30/392; G06F 30/394

(57) ABSTRACT

Implementing a circuit design for a target integrated circuit includes receiving guide information including placement information for a circuit design from a prior implementation flow. A light incremental flow is performed on the circuit design using the guide information. The light incremental flow generates a placed and routed circuit design that re-uses at least a portion of the placement information from the prior implementation flow.

### TECHNICAL FIELD

This disclosure relates to integrated circuits (ICs) and, more particularly, to placing and routing circuit designs for ICs.

### BACKGROUND

Modern System-on-Chips (SoCs) continue to increase in size and often include a variety of different types of circuitry and/or subsystems. Increasing heterogeneity and size of the devices means that the designs implemented in these devices are similarly large and complex. Creating a functional design that takes advantage of this heterogeneity and that meets stringent performance requirements is exceedingly difficult. Failing to achieve timing closure for any part of the design, for example, may impact the functionality of the entire design.

A variety of different techniques for achieving timing closure are available. Some techniques seek to close timing of a design using an iterative approach that applies different timing closure strategies in different iterations. After each iteration, analysis tools operate on the design as implemented to select timing closure strategies to be tried in the next iteration. Iterative approaches are often very time consuming with compilation times running significantly longer than compile times of conventional implementation flows.

Other techniques utilize incremental compilation. Incremental compilation techniques use a prior placed and routed design as input to an implementation flow. While incremental compilation has been successfully applied to incremental changes to a design, there are disadvantages. These include the need to maintain a sizable database of design data for reuse. Further, modern, heterogeneous SoCs, incremental compilation has not been able to generate predictable design implementations. That is, aspects of the implemented design such as the placement and/or routing tend to vary significantly from the initially placed and routed solution, which makes the technique less reliable and less capable of producing an implementation with consistent Quality of Result.

### SUMMARY

In one or more examples, a method includes receiving guide information including placement information for a circuit design from a prior implementation flow. The method includes performing a light incremental flow on the circuit design using the guide information. The light incremental flow generates a placed and routed circuit design that re-uses at least a portion of the placement information from the prior implementation flow.

The foregoing and other implementations can each optionally include one or more of the following features, alone or in combination. Some example implementations include all the following features in combination.

In some aspects, the placement information specifies location information for one or more logical components of the circuit design placed at a hard macro.

In some aspects, the placement information specifies location information for one or more logical components of the circuit design placed at an input/output (I/O) block.

In some aspects, the placement information specifies location information for one or more logical components of the circuit design placed at a Network-on-Chip (NoC) interface.

In some aspects, the placement information specifies location information for one or more logical components of the circuit design placed at a clocking component.

In some aspects, the placement information specifies location information for one or more logical components of the circuit design coupled to an inter-die connection.

In some aspects, the method includes iteratively matching logical components of the circuit design during the light incremental flow with logical components specified in the guide information and using the placement information from the guide information for the matched logical components of the circuit design during placement of the light incremental flow.

In some aspects, the guide information defines a plurality of constraints specified as human readable data in a file.

In some aspects, only a subset of the guide information as selected by a user is used during the light incremental flow.

In some aspects, at least a portion of the guide information is modified by a user and used, as modified, during the light incremental flow.

In some aspects, the circuit design as processed through the light incremental flow is a modified version of the circuit design processed through the prior implementation flow.

In some aspects, a different version of a computer-based implementation tool performs the light incremental flow than the prior implementation flow.

In one or more examples, a system includes a hardware processor and one or more computer-readable storage media storing program instructions to cause the hardware processor to perform operations. The operations include receiving guide information including placement information for a circuit design from a prior implementation flow. The operations include performing a light incremental flow on the circuit design using the guide information. The light incremental flow generates a placed and routed circuit design that re-uses at least a portion of the placement information from the prior implementation flow.

In one or more examples, the techniques described herein relate to a computer program product that includes one or more computer-readable storage media and program instructions stored on the one or more computer-readable storage media to perform operations. The operations include receiving guide information including placement information for a circuit design from a prior implementation flow. The operations include performing a light incremental flow on the circuit design using the guide information. The light incremental flow generates a placed and routed circuit design that re-uses at least a portion of the placement information from the prior implementation flow.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the implementations to only the examples shown. Various aspects and advantages will become apparent upon review of the following detailed description and upon reference to the drawings.

FIG. 1 illustrates an example of an executable framework in accordance with one or more implementations of the disclosed technology.

FIG. 2 illustrates an example integrated circuit (IC) for which guide information may be generated.

FIG. 3 illustrates an example of a guide file specifying guide information.

FIG. 4 illustrates another example IC for which guide information may be generated.

FIG. 5 illustrates an example architecture for a Network-on-Chip (NoC) of an IC for which guide information may be generated.

FIG. 6 illustrates an example of endpoint circuits of an IC connecting through a NoC.

FIG. 7 illustrates another example of a NoC of an IC for which guide information may be generated.

FIG. 8 illustrates an example of clocking circuitry of an IC for which guide information may be generated.

FIG. 9 illustrates an example a clock expansion window for which guide information may be generated.

FIG. 10 illustrates an example method of operation for a data processing system executing the framework of FIG. 1.

FIG. 11 illustrates an example of a data processing system for use with the example implementations described herein.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to placing and routing circuit designs for ICs. The disclosed technology provides methods, systems, and computer program products for an incremental implementation flow, also referred to as a “light incremental technology,” that enables Quality-of-Result (QoR) resilience when applied to a same circuit design. The disclosed technology is capable of guiding implementation tools such as place and route tools to achieve consistent outcomes for a circuit design. The disclosed technology is capable of achieving consistent outcomes for a circuit design that has been modified. In one or more examples, the disclosed technology is capable of achieving consistent outcomes for a circuit design that has been modified with one or more deterministic changes. A deterministic change is one that has a known impact on the implementation of the circuit design as processed through an implementation flow.

In one or more examples, a system is disclosed that is capable of implementing a multi-step process for implementing a circuit design. The system is capable of processing a circuit design for an IC through a reference implementation flow. From the reference implementation flow, the system is capable of generating pertinent data referred to herein as “guide information,” that may be provided as input to a subsequent light incremental flow. The circuit design may be processed through the light incremental flow using the guide information, or selected portions of the guide information, from the reference implementation flow. The output generated by the light incremental flow, i.e., the circuit design as implemented, has a particular or measurable Quality-of-Result (QoR). In the examples, the QoR of the circuit design obtained from the light incremental flow is approximately equal to that of the result obtained from the reference implementation flow. In this regard, the QoR is said to be resilient. As such, the light incremental technology disclosed herein provides more reliable results with greater consistency in QoR than other available techniques.

In one or more examples, the guide information that is generated has a lighter footprint than other types of data utilized in other iterative circuit design implementation techniques. For example, the guide information may be generated as a plurality of constraints that may be specified in a single file. In one or more examples, the guide information may be specified as human readable text which allows a user to edit the guide information prior to providing that guide information to the light incremental flow if desired.

By comparison, conventional incremental techniques seek to preserve the entirety of the design data for the circuit design that has been generated from an implementation flow. In some cases, the design data for the circuit design is preserved from multiple, different iterations of the implementation flow. Often, this design data is saved in a database as design checkpoint data. This design data is large in size as it contains design data pertaining to each of the various stages of the implementation flow (e.g., synthesis, placement, routing, etc.). For purposes of illustration, a database storing design checkpoint data may be multiple gigabytes in size while a file including guide information as disclosed herein may be approximately 10-20 megabytes or less. The smaller size of the guide information means that the disclosed technology requires significantly fewer computational resources (e.g., less processing or CPU power, less runtime memory, and/or less data storage) than other conventional incremental techniques.

The disclosed technology may be used in a variety of different contexts to provide consistent QoR for circuit designs. For example, the disclosed technology may be used in cases where a circuit design undergoes an incremental change. The circuit design prior to implementing an incremental change is processed through the reference implementation flow with guide information being generated. Subsequent to the incremental change, the circuit design is processed through the light incremental flow using the guide information. The resulting implementation of the incrementally changed circuit design will have a QoR that is equal to, or approximately equal to, that of the circuit design as implemented through the reference implementation flow. Within this disclosure, QoR of a circuit design or implementation thereof refers to the timing performance of the circuit design and, for example, whether the timing of the circuit design meets established design requirements. In some examples, the QoR of a circuit design may be specified as the worst negative slack or “WNS” of the circuit design achieved by the implementation flow.

The disclosed technology also may be used in cases where the EDA tool itself has evolved or been developed to a new version or generation. In that case, for example, a circuit design may have been processed through a reference implementation flow by a prior version of an electronic design automation (EDA) tool thereby producing guide information. The circuit design may then be processed through a light incremental flow by a next or newer version of the EDA tool using the guide information. The QoR of the circuit design implementation from the light incremental flow will be equal to, or approximately equal to, the QoR of the circuit design from the reference implementation flow. In this example, the circuit design may or may not have been incrementally changed from the reference implementation flow to the light incremental flow.

The disclosed technology facilitates achieving consistent QoR whether a circuit design has undergone change or is being processed by newer/different versions of the implementation tools. In some examples, the guide information provides flexibility to the light incremental flow such that an improved QoR may be achieved.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

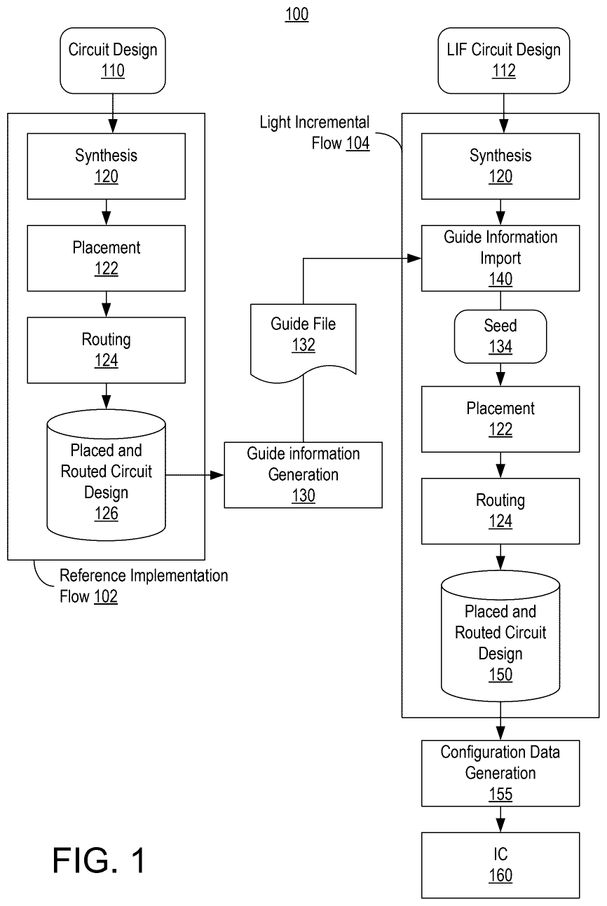

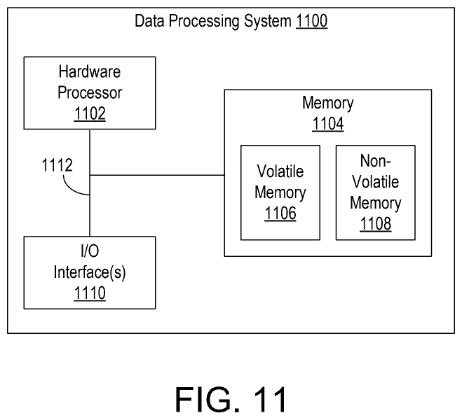

FIG. 1 illustrates an example of an executable framework in accordance with one or more implementations of the disclosed technology. The operations illustrated in FIG. 1 may be performed, or executed, by a data processing system executing suitable program instructions. The program instructions may be embodied as an EDA or implementation tool executing on a data processing system (system). An example of a data processing system that is capable of executing framework 100 is described herein in connection with FIG. 11.

In the example, framework 100 includes a reference implementation flow 102 and a light incremental flow 104. Reference implementation flow 102 is capable of operating on circuit design 110. Light incremental flow 104 is capable of operating on a circuit design referred to herein as LIF (light incremental flow) circuit design 112. LIF circuit design 112 may be the same as, e.g., identical to, circuit design 110 or may be a modified version of circuit design 110.

The term “circuit design” refers to one or more register transfer level (RTL) description modules. A circuit design may refer to an entire circuit design that includes user specified RTL; one or more cores and/or intellectual properties (IPs); a combination of user specified RTL, cores, and/or IP; a single IP and/or core (e.g., a reusable portion of RTL); or the like. The term “module,” in this context, refers to a unit of RTL. A module is a defined construct within the syntax of the particular hardware description language (HDL) used to express the RTL description and is part of a hierarchical organization of modules forming the circuit design.

Implementing a circuit design within an IC entails processing the circuit design through a plurality of stages of an implementation flow. In the example of FIG. 1, circuit design 110 is processed through an implementation flow illustrated as reference implementation flow 102. Reference implementation flow 102 includes a plurality of stages such as, for example, synthesis 120, placement 122, and routing 124. In general, synthesis 120 refers to the process of generating a gate-level netlist from an RTL description of a design (e.g., circuit design 110). The netlist may be technology specific in that the netlist is intended for implementation in a particular IC such as IC 160. The particular IC in which the circuit design is to be physically realized is also referred to herein as a “target IC.” Placement 122 refers to the process of assigning elements of the synthesized circuit design to particular instances of circuit blocks, e.g., primitives, and/or other resources having specific locations on the target IC. In some cases, the primitives or resources with specific locations are referred to as “sites.” Routing 124 refers to the process of selecting or implementing particular routing resources, e.g., wires and/or other interconnect circuitry, to electrically couple the various circuit blocks of the target IC after placement 122.

In the example, reference implementation flow 102 generates a placed and routed circuit design 126 (e.g., a placed and routed version of circuit design 110). In one or more examples, placed and routed circuit design 126 is stored as design checkpoint data. In many cases, the design checkpoint data specifying placed and routed circuit design 126 is stored in a database or as a plurality of files as part of a hierarchical file system. In some cases, the design checkpoint data is stored as a design checkpoint file that is typically a compressed file such as an archive file that preserves the directory structure and file hierarchy of the design checkpoint data. The design checkpoint data often includes information generated in each of the different stages of an implementation flow and, as such, is large in size. The design checkpoint data is typically many gigabytes in size.

While design checkpoint data is capable of specifying a fully placed and routed version of a circuit design, the data is so large that it is not easily transferred to other data processing systems or easily used in the context of an incremental implementation flow. Storing multiple versions of the placed and routed design as design checkpoint data requires even more storage and becomes impractical.

For purposes of illustration, the stages of reference implementation flow 102 illustrated in FIG. 1 have been simplified. An actual implementation flow often includes one or more additional optimization stages. Such optimization stages may follow synthesis, placement and/or routing with each optimization stage further refining the operations performed to achieve improved QoR than would otherwise not have been attained.

Once circuit design 110 is processed and design checkpoint data is generated, guide information generation 130 is performed. Guide information generation 130 is a process in which selected items of information are extracted from placed and routed circuit design 126, e.g., from the design checkpoint data. The guide information may be extracted at any point within reference implementation flow 102 subsequent to successful routing of circuit design 110. The extracted guide information may be written to a guide file 132. In one or more examples, framework 100 may provide an Application Programming Interface (API) including a function such as “write_guide_info” that is capable of parsing placed and routed circuit design 126, selecting data items for extraction, extracting the data items, and writing the data items as extracted to guide file 132.

In one or more implementations, guide file 132 may be specified as a text file containing the guide information in the form of human readable text. In one or more examples, guide file 132 may be specified as a JSON file. Guide file 132 may specify the guide information extracted from design checkpoint data as a plurality of design constraints. By providing guide file 132 specifying guide information in a human readable format, a user is capable of opening and editing contents, e.g., the guide information, within guide file 132 prior to providing guide file 132 to light incremental flow 104. A user, for example, may modify existing constraints, delete constraints, or add new constraints to guide file 132. Further, by specifying guide information as constraints, the size of guide file 132 may be significantly smaller than the size of the design checkpoint data specifying placed and routed circuit design 126. As noted, while design checkpoint data is typically many gigabytes in size, guide file 132 is typically 10-20 megabytes and less in some cases. The relatively small size of guide file 132 allows a variety of different versions of the file to be created, cataloged, and saved for subsequent use. Further, guide file 132 is highly portable from one data processing system to another.

In one or more other examples, the guide information specified in guide file 132 may be specified in other formats. For purposes of illustration, the guide information may be specified in non-human readable formats. Examples of non-human readable formats may include, but are not limited to, binary file formats, compressed file formats (e.g., .zip files, .rar files, and/or other container files), database file formats (e.g., SQL files and/or BSON file), or the like. The examples provided herein are not intended to be limiting of the disclosed technology.

In one or more examples, guide file 132 includes a plurality of different sections, where each section specifies a different type of data. Each section may specify placement information for a particular type of logical component of circuit design 110. The sections may include, but are not limited to, a hard macro section, an input/output (I/O) section, a Network-on-Chip (NoC) section, a clocking section, and a Super Logic Region (SLR) crossing section. The term “Super Logic Region” or “SLR” refers to a die of a target IC. Each section of guide file 132 specifies placement information for a particular type or class of logical component of circuit design 110 that, if followed or used by light incremental flow 104, results in a placed and routed circuit design 150 that has a QoR that is substantially the same as that of placed and routed circuit design 126. In other words, the information specified in each section of guide file 132 has been identified as ensuring repeatability and/or reliability in implementing and/or reimplementing a circuit design or modified version thereof.

Accordingly, a further implementation flow illustrated as light incremental flow 104 may be performed on LIF circuit design 112. Light incremental flow 104 includes stages such as synthesis 120, placement 122, and routing 124. These stages may be implemented substantially as described in connection with reference implementation flow 102. In the example, light incremental flow 104 may be performed on LIF circuit design 112.

In one or more examples, reference implementation flow 102 may be performed by a particular version or build of an EDA tool while light incremental flow 104 may be performed by a different version or build of the same EDA tool. As an example, circuit design 110 may be created and later require re-implementation using a newer version of the EDA tool. In this example, the same circuit design may be processed through each of reference implementation flow 102 and light incremental flow 104 (e.g., LIF circuit design 112 is the same as circuit design 110). In this example, re-implementation of the circuit design is needed to maintain compatibility of the circuit design and design data with future iterations of the EDA tool. Still, in reimplementing the circuit design using the new version of the EDA tool, there is no guarantee that a similar or same QoR will be achieved as was achieved via the earlier reference implementation flow. The example framework of FIG. 1 ensures that a similar or same QoR will be achieved.

In one or more other examples, circuit design 110 may be modified in some manner. That is, a user may make a change or modification to circuit design 110 (e.g., where LIF circuit design 112 is a modified version of circuit design 110). In this case, while circuit design 110 is processed through reference implementation flow 102, LIF circuit design 112 may be processed through light incremental flow 104. In this example, re-implementation of the modified version of the circuit design through by the same EDA tool still does not guarantee a similar or same QoR will be achieved as was achieved by reference implementation flow 102 operating on circuit design 110. The example framework of FIG. 1 ensures that a similar or same QoR will be achieved for the modified version of the circuit design as for the original (e.g., unmodified version) of the circuit design.

In the example, light incremental flow 104 is differentiated from reference implementation flow 102 in that light incremental flow 104 includes a stage illustrated as guide information import 140. Guide information import 140 is capable of receiving and/or reading guide information from guide file 132 and providing the guide information or portions thereof to placement 122 as seed 134. The guide information is from the reference implementation flow 102, e.g., a prior implementation flow. In one or more examples, seed 134 may include the entirety of the contents from guide file 132 and, as such, be embodied as guide file 132. In one or more other examples, seed 134 includes only selected portions from guide file 132. Information contained in seed 134 may be specified as one or more constraints that are observed, to the extent possible, by placement 122. Placement 122 is capable of applying any constraints specified by seed 134 prior to performing placement.

In one or more examples, guide information import is capable of importing guide file 132 and generating seed 134. In generating seed 134, guide information import 140 may query the user, e.g., via a user interface, as to whether the user wishes to modify guide file 132 and/or select only particular portions of guide file 132 to use for light incremental flow 104.

In one or more examples, a user may select different portions of guide file 132 to provide as seed 134 (thereby omitting the non-selected portions of guide file 132) to placement 122 of light incremental flow 104. A user also may modify or edit guide file 132 and create different versions of guide file 132 and/or seed 134. These different versions guide file 132 and/or of seed 134 may be ranked and/or compared with one another based on the achieved QoR of light incremental flow 104 using each respective version. Once the user has made any needed selections and/or modifications, guide information import 140 may generate seed 134 by implementing the user's instructions.

Seed 134 directs different stages of light incremental flow 104 such as placement 122 to discover a similar or potentially better placement solution for LIF circuit design 112. By providing seed 134 to placement 122 of light incremental flow 104, framework 100 is provided with improved direction and a starting point that does not sacrifice flexibility of the system to seek marginally different solutions.

As noted, QoR may be specified in terms of timing or clock speed of the placed and routed circuit design. In one or more examples, QoR may be specified in terms of WNS. In the example of FIG. 1, for placed and routed circuit design 126 to have a QoR that is substantially the same as the QoR of placed and routed design 150, both resulting implementations will meet established timing constraints, have substantially similar timing, and/or have substantially similar WNS.

Placed and routed circuit design 150 is generated by light incremental flow 104 operating on LIF circuit design 112. Placed and routed circuit design 150 may be processed through configuration data generation 155 that generates the configuration data, e.g., a bitstream or configuration bitstream, that may be loaded into IC 160. Loading the configuration data into IC 160 physically implements, or realizes, placed and routed circuit design 150 within IC 160.

In one or more examples, light incremental flow 104 also may generate reporting data (not shown). The reporting data may specify particular metrics indicating how seed 134 was honored by placement 122 in light incremental flow 104. In one or more examples, placement 122 may generate the reporting data. The reporting data may indicate how many of each different type of logical component of LIF circuit design 112 were placed at the location or using the location information of seed 134. The reporting data also may indicate or provide a reason why a location violation occurred (e.g., a particular logical component specified in seed 134 not being found or having an analog in LIF circuit design 112.

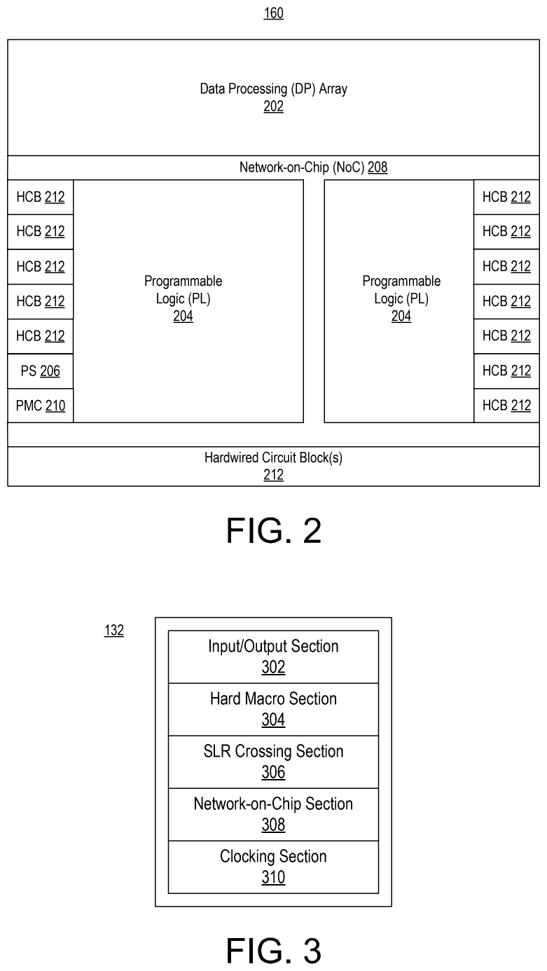

FIG. 2 illustrates an example implementation of IC 160. IC 160 may be an adaptive system (e.g., a programmable IC) and/or a System-on-Chip (SoC). In the example of FIG. 2, IC 160 is implemented on a single die provided within a single package. In other examples, IC 160 may be implemented using a plurality of interconnected dies within a single package where the various resources of IC 160 (e.g., circuits) illustrated in FIG. 2 are implemented or distributed across the different interconnected dies. In still other examples, the multiple dies each may have a circuit architecture the same as or similar to that illustrated in FIG. 2. In any case, the dies are coupled together and included in a single package as a multi-die IC.

In the example, IC 160 includes a plurality of different subsystems including a data processing (DP) array 202, programmable logic (PL) 204, a processor system (PS) 206, a Network-on-Chip (NoC) 208, a platform management controller (PMC) 210, and one or more hardwired circuit blocks 212.

DP array 202 is implemented as a plurality of interconnected and programmable compute tiles and/or memory tiles. Compute and/or memory tiles may be arranged in an array and are hardwired. Each compute tile can include one or more cores and a random-access memory (RAM). Each memory tile may include a RAM. In one example implementation, cores of the compute tiles may be implemented as custom circuits that do not execute program code. In another example implementation, cores of the compute tiles are capable of executing program code stored in core-specific program memories contained within each respective core.

As an example, a core of a compute tile may be implemented as a vector processor capable of performing both fixed and floating-point operations and/or a scalar processor. Each compute tile further includes a RAM and dedicated multi-bit data movement channels connecting the compute tiles. Each compute tile further can include support for direct memory access (DMA) operations and locks to move data to and from other compute tiles.

DP array 202 may include a DP interface that connects compute tiles or memory tiles to other resources of IC 160. The DP interface may include a plurality of interconnected interface tiles organized in a row. In one example, each interface tile may have a same architecture. In another example, interface tiles may be implemented with different architectures where each different interface tile architecture supports communication with different types of resources of IC 160. Interface tiles of the DP interface are connected so that data may be propagated from one interface tile to another bi-directionally. Each interface tile is capable of operating as an interface for the column of compute tiles and/or memory tiles directly above.

PL 204 is circuitry that may be programmed to perform specified functions. As an example, PL 204 may be implemented as field programmable gate array type of circuitry. PL 204 can include an array of programmable circuit blocks. As defined herein, the term “programmable logic” means circuitry used to build reconfigurable digital circuits. Programmable logic is formed of many programmable circuit blocks that provide basic functionality. The topology of PL 204 is highly configurable unlike hardwired circuitry. In one aspect, each programmable circuit block of PL 204 includes a programmable functional circuit and a programmable interconnect circuit. The programmable interconnect circuits provide the highly configurable topology of PL 204. The programmable interconnect circuits may be configured on a per wire basis to provide connectivity among the programmable functional circuits of programmable circuit blocks of PL 204 and is configurable on a per-bit basis (e.g., where each wire conveys a single bit of information) unlike connectivity among the compute tiles and/or memory tiles in DP array 202, for example.

Examples of programmable circuit blocks of PL 204 include configurable logic blocks (CLBs) having look-up tables (LUTs) and registers. Unlike hardwired circuitry described below and sometimes referred to as hardwired circuit blocks, these programmable circuit blocks have an undefined function at the time of manufacture. PL 204 may include other types of programmable circuit blocks that also provide basic and defined functionality with more limited programmability. Examples of these circuit blocks, which are also referred to as “hard macros,” may include digital signal processing blocks (DSPs), Block RAMs (BRAMs), and Ultra-RAMs (URAMs).

In general, a hard macro refers to a pre-designed and pre-routed circuit block of an IC. Hard macros are larger circuit tiles that may be limited in availability compared to CLBs. Within PL 204, hard macros may be intermingled with the other programmable circuit blocks of PL 204 (e.g., intermingled with CLBs). Hard macros still have an architecture that generally includes a programmable interconnect circuits and programmable functional circuits and, as such, are part of the highly configurable topology of PL 204. Hard macros are a type of primitive available on IC 160.

Prior to use, PL 204, e.g., the programmable interconnect and the programmable elements, must be programmed or “configured” by loading data referred to as a configuration bitstream into internal configuration memory cells therein. The configuration memory cells, once loaded with a configuration bitstream, define how PL 204 is configured, e.g., the topology, and operates (e.g., particular functions performed).

PS 206 is implemented as hardwired circuitry that is fabricated as part of IC 160. PS 206 may be implemented as, or include, any of a variety of different processor types each capable of executing program code. For example, PS 206 may be implemented as an individual processor, e.g., a single core capable of executing program code. In another example, PS 206 may be implemented as a multi-core processor. In still another example, PS 206 may include one or more cores, modules, co-processors, I/O interfaces, and/or other resources. PS 206 may be implemented using any of a variety of different types of architectures. Example architectures that may be used to implement PS 206 may include, but are not limited to, an ARM processor architecture, an x86 processor architecture, a graphics processing unit (GPU) architecture, a mobile processor architecture, a DSP architecture, combinations of the foregoing architectures, or other suitable architecture that is capable of executing computer-readable instructions or program code.

NoC 208 is a programmable interconnecting network for sharing data between endpoint circuits in IC 160. The endpoint circuits can be disposed in DP array 202, PL 204, PS 206, and/or selected hardwired circuit blocks 212. The endpoint circuits may couple to NoC 208 through NoC master units (e.g., a controller or primary interface) and/or NoC slave units (e.g., a follower or secondary interface). NoC 208 can include high-speed data paths with dedicated switching. In an example, NoC 208 includes one or more horizontal paths, one or more vertical paths, or both horizontal and vertical path(s). The arrangement and number of regions shown in FIG. 2 is merely an example. NoC 208 is an example of the common infrastructure that is available within IC 160 to connect selected components and/or subsystems.

Nets that are to be routed through NoC 208 may be unknown until a design is created for implementation within IC 160. NoC 208 may be programmed by loading configuration data into internal configuration registers that define how elements within NoC 208 such as switches and interfaces are configured and operate to pass data from switch to switch and among the NoC interfaces to connect the endpoint circuits. NoC 208 is fabricated as part of IC 160 (e.g., is hardwired) and, while not physically modifiable, may be programmed to establish logical connectivity between different controller circuits and different follower circuits of a user circuit design. NoC 208, upon power-on, does not implement any data paths or routes therein. Once configured by a particular circuit with configuration capability such as PMC 210, however, NoC 208 implements data paths or routes between endpoint circuits.

PMC 210 is responsible for managing IC 160. PMC 210 is a subsystem within IC 160 that is capable of managing the other programmable circuit resources across the entirety of IC 160. PMC 210 is capable of maintaining a safe and secure environment, booting IC 160, and managing IC 160 during normal operations. For example, PMC 210 is capable of providing unified and programmable control over power-up, boot/configuration, security, power management, safety monitoring, debugging, and/or error handling for the different subsystems of IC 160 (e.g., DP array 202, PL 204, PS 206, and NoC 208). PMC 210 operates as a dedicated platform manager that decouples PS 206 from PL 204. As such, PS 206 and PL 204 may be managed, configured, and/or powered on and/or off independently of one another.

Hardwired circuit blocks 212 are special-purpose circuit blocks fabricated as part of IC 160. Though hardwired, hardwired circuit blocks 212 may be configured by loading configuration data into control registers to implement one or more different modes of operation. Examples of hardwired circuit blocks 212 may include I/O blocks, transceivers for sending and receiving signals to circuits and/or systems external to IC 160, memory controllers, or the like. Examples of different I/O blocks may include single-ended and pseudo differential I/Os. Examples of transceivers may include high-speed differentially clocked transceivers. Other examples of hardwired circuit blocks 212 include, but are not limited to, cryptographic engines, digital-to-analog converters (DACs), analog-to-digital converters (ADCs), and the like. In general, hardwired circuit blocks 212 are application-specific circuit blocks.

The various programmable circuit resources illustrated in FIG. 2 may be programmed initially as part of a boot process for IC 160. During runtime, the programmable circuit resources may be reconfigured. In one aspect, PMC 210 is capable of initially configuring DP array 202, PL 204, PS 206, and NoC 208. At any point during runtime, PMC 210 may reconfigure all or a portion of IC 160. In some cases, PS 206 may configure and/or reconfigure PL 204 and/or NoC 208 once initially configured by PMC 210.

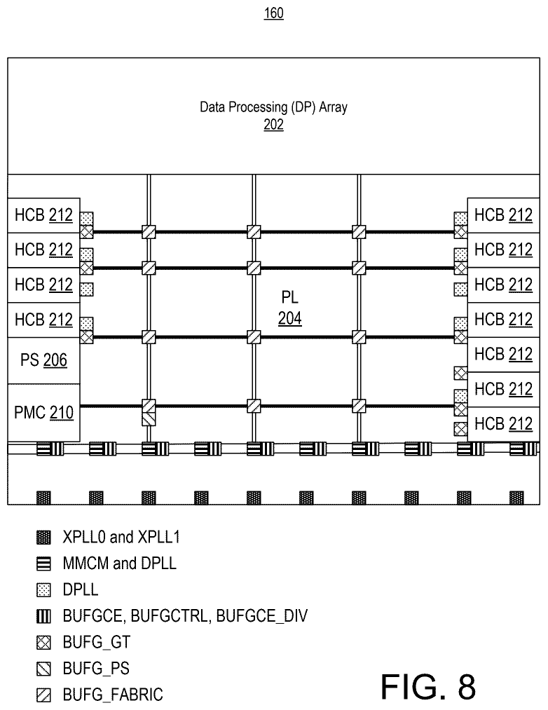

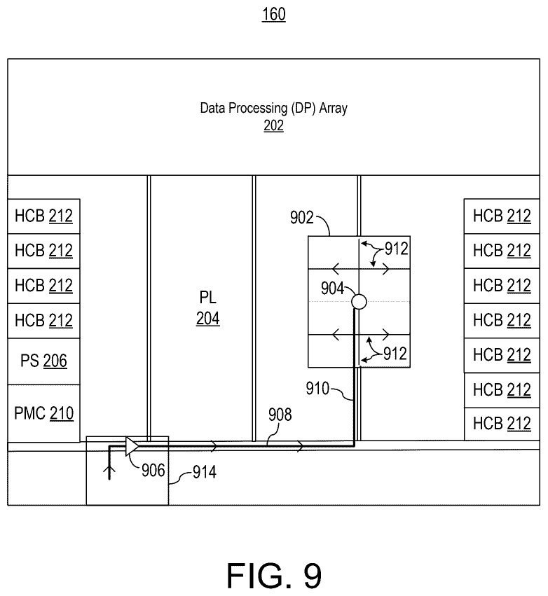

IC 160 is provided as an example of a heterogeneous IC. Other example architectures may include other combinations of the particular circuits and/or subsystems described. As noted, in multi-die IC configurations, each die may be identical or include different combinations of circuits and/or subsystems. For purposes of illustration, clocking circuitry of IC 160 is not illustrated in the example of FIG. 2. Example clocking circuitry is described in connection with the examples of FIGS. 8 and 9.

FIG. 3 illustrates an example of guide file 132 of FIG. 1 in accordance with one or more implementations of the disclosed technology. In the example of FIG. 3, guide file 132 includes a plurality of different sections each specifying a different type of guide information that may be used to create seed 134 for use during light incremental flow 104. In the example, guide file 132 includes a plurality of different sections. In the example, guide file 132 includes an I/O section 302, a hard macro section 304, an SLR crossing section 306, a NoC section 308, and a clocking section 310. As discussed, each section specifies placement information for a particular type or class of logical component of circuit design 110. In one or more examples, the location information in each of sections 302-310 may be specified hierarchically.

The I/O section 302 specifies location information for logical components of circuit design 110 that represent I/O blocks of the target IC. For example, I/O section 302 may include a list of each logical component of circuit design 110 that has been synthesized as an I/O block and placed at an I/O block of the target IC. I/O section 302 may specify one or more or all such logical components (e.g., “I/O logical components) of circuit design 110 and location information. The location information of I/O section 302 may specify a location to which each I/O logical component has been placed in the target IC by placement 122 of reference implementation flow 102.

In one or more examples, location information specifies a location to which a logical component of circuit design 110 has been placed. The location may be specified as a coordinate. For example, the coordinate may be specified as an x-y coordinate that maps onto an x-y coordinate system that is superimposed on the target IC. Each location may specify a physical site, e.g., primitive, of the target IC to which the logical component has been placed. In the case where the target IC includes more than one die, a die indicator specifying the particular die in which the logical component has been placed also may be specified as part of the location.

FIG. 3 is provided for purposes of illustration and not limitation. In other examples, guide file 132 may include one or more other sections not illustrated in the example of FIG. 3. For example, guide file 132 may include a routing section that specifies routing information for circuit design 110. The routing information may specify usage of one or more selected or particular routing resources. For example, the use of inter-die wires may be specified as part of the routing information.

The guide information and/or sections specified in guide file 132 may specify information other than location-based information. For example, property information for particular aspects of circuit design 110 and/or for components and/or primitives used in circuit design 110 may be specified in guide file 132 and may be specified in a separate and/or dedicated section thereof. In still other examples, fewer than all of the sections illustrated in FIG. 3 may be included in guide file 132. For example, any combination of the different sections illustrated in FIG. 3 may be included in guide file 132 such that one or more sections are omitted or left empty.

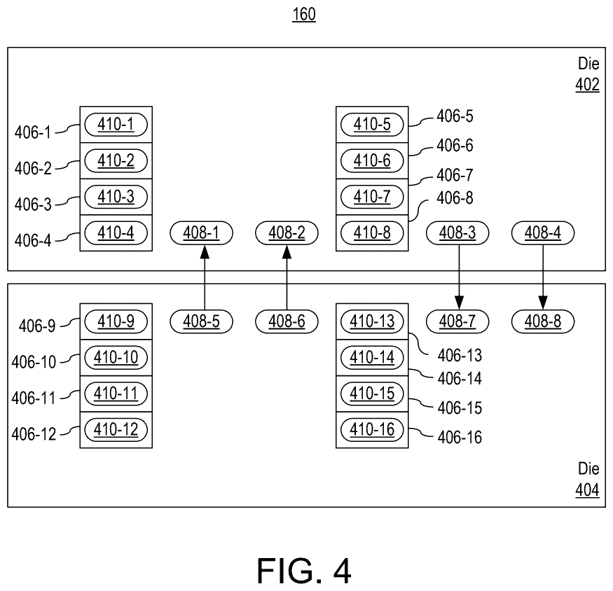

FIG. 4 illustrates another example implementation of IC 160 for which guide information may be generated in accordance with one or more implementations of the disclosed technology. FIG. 4 illustrates certain circuit structures of IC 160 corresponding to hard macro section 304 and SLR crossing section 306 of guide file 132. While SLR crossing section 306 explicitly deals with target ICs that include multiple dies, hard macro section 304 may specify guide information in cases where the target IC includes a single die or multiple dies.

In the example of FIG. 4, IC 160 is implemented as a multi-die IC including a die 402 and a die 404. Dies 402 and 404 are coupled by any of a variety of multi-die connection technologies. In some examples, dies 402 and 404 may be stacked where dies 402 and 404 communicate by way of connections between the dies referred to herein as “inter-die wires” that may be implemented as vias. In other examples, dies 402 and 404 may be disposed on an interposer and communicate through inter-die wires within the interposer.

In the example, each of dies 402, 404 includes a plurality of hard macro sites 406. For purposes of illustration, hard macro sites 406 may be disposed in regions such as PL 204 of IC 160 and are a type of available primitive. Examples of hard macro sites 406 include, but are not limited to, BRAMs, URAMs, and DSPs. In some examples, hard macro sites 406 are arranged in one or more columns within regions of PL 204. In most cases, hard macros are limited in terms of number and availability on a target IC and also are available in only limited locations, placement information for such structures may be used to guide light incremental flow 104. In the example, each of dies 402, 404 includes a plurality of hard macro sites 406.

Hard macro section 304 may specify, for each logical component of circuit design 110 that has been synthesized and placed to a hard macro site 408, the name of the logical component and a location to which the logical component of circuit design 110 has been placed for the target IC by placement 122 of reference implementation flow 102. For example, hard macro section 304 may specify that logical component 410-1 is located at hard macro site 406-1 (e.g., at the location of hard macro site 406-1), that logical component 410-2 is located at hard macro site 406-2, and so forth for each logical component 410 determined to specify or correspond to a hard macro. In cases where the target IC includes multiple dies, the particular die may be specified also for each component assigned or placed to a hard macro site 408.

SLR crossing section 306 may specify, each logical component 410 of circuit design 110 that participates in an inter-die connection. An inter-die connection refers to a connection between logical components placed in different dies of a multi-die target IC that connect via an inter-die wire. The number of inter-die signals (e.g., die or SLR crossings) of a circuit design as placed is a significant metric from a resource utilization and performance perspective. Keeping the number of inter-die signals of circuit design 110, as placed, to a minimum improves the QoR of the circuit design. Maintaining the number of inter-die signals constant or substantially similar from one implementation flow to the next facilitates stability in the implementation of the circuit design.

In the example of FIG. 4, each logical component 410 that is placed at an endpoint circuit of the target IC that couples to (e.g., connects to) an inter-die wire may be specified in SLR crossing section 306. Accordingly, in one or more examples, SLR crossing section 306 may specify the particular logical components placed at sites that connect to an inter-die wire and the particular die in which that logical component is placed. In the example of FIG. 4, SLR crossing section 306 specifies that logical components 408-1, 408-2, 408-3, and 408-4 are located in die 402, while logical components 408-5, 408-6, 408-7, and 408-8 are located in die 404.

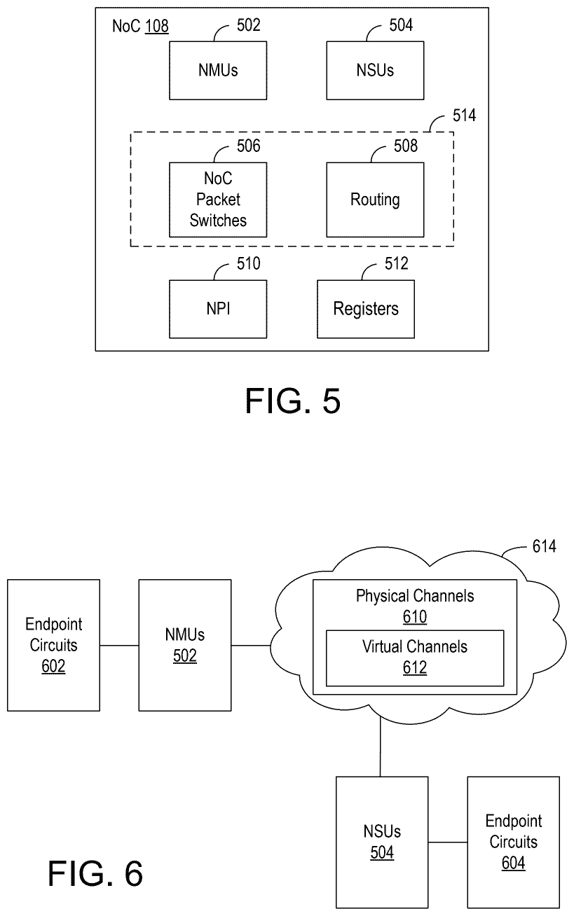

FIGS. 5, 6, and 7 are block diagrams illustrating certain operative features of NoC 108 that may be captured as guide information within NoC section 308 of guide file 132 in accordance with one or more implementations of the disclosed technology.

FIG. 5 illustrates an example circuit architecture for NoC 108. In the example of FIG. 5, NoC 108 includes NoC master units (NMUs) 502, NoC slave units (NSUs) 504, a network 514, NoC peripheral interconnect (NPI) 510, and registers 512. Each NMU 502 may operate as an ingress interface circuit that connects an endpoint circuit to NoC 108. Each NSU 504 may operate as an egress interface circuit that connects NoC 108 to an endpoint circuit. The NMUs 502 are connected to the NSUs 504 through network 514. A given endpoint circuit can be coupled to more than one NMU 502 or more than one NSU 504.

In an example, network 514 includes NoC packet switches 506 (“NPSs”) and routing 508 between NPSs 506. Each NPS 506 performs switching of NoC packets. NPSs 506 are connected to each other and to NMUs 502 and NSUs 504 through routing 508 to implement a plurality of physical channels. NPSs 506 also support multiple virtual channels per physical channel. NPI 510 includes circuitry to program NMUs 502, NSUs 504, and NPSs 506. For example, NMUs 502, NSUs 504, and NPSs 506 can include registers 512 that determine functionality thereof. NPI 510 includes a peripheral interconnect coupled to the registers 512 for programming thereof to set functionality. Registers 512 in NoC 108 support interrupts, QoS, error handling and reporting, transaction control, power management, and address mapping control. Registers 512 can be initialized in a usable state before being reprogrammed, such as by writing to registers 512 using write requests. Configuration data for NoC 108 can be stored in a non-volatile memory (NVM) and provided to NPI 510 for programming NoC 108 and/or other endpoint circuits.

FIG. 6 is a block diagram depicting endpoint circuits of IC 160 connecting through NoC 108 according to one or more examples of the disclosed technology. In the example, endpoint circuits 602 are connected to endpoint circuits 604 through NoC 108. Endpoint circuits 602 are master circuits, which are coupled to NMUs 502 of NoC 108. Endpoint circuits 604 are slave circuits coupled to NSUs 504 of NoC 108. Each endpoint circuit 602 and 604 can be a circuit or circuits in DP array 202, in PS 206, in PL 204, or in another subsystem (e.g., hardwired circuit blocks 212).

Network 614 includes a plurality of physical channels 610. Physical channels 610 are implemented by programming NoC 108. Each physical channel 610 includes one or more NoC packet switches 506 and associated routing 508. An NMU 502 connects with an NSU 504 through at least one physical channel 610. A physical channel 610 can also have one or more virtual channels 612.

Connections through the network 614 use a master-slave arrangement. In an example, the most basic connection over network 614 includes a single master circuit connected to a single slave circuit. However, in other examples, more complex structures can be implemented.

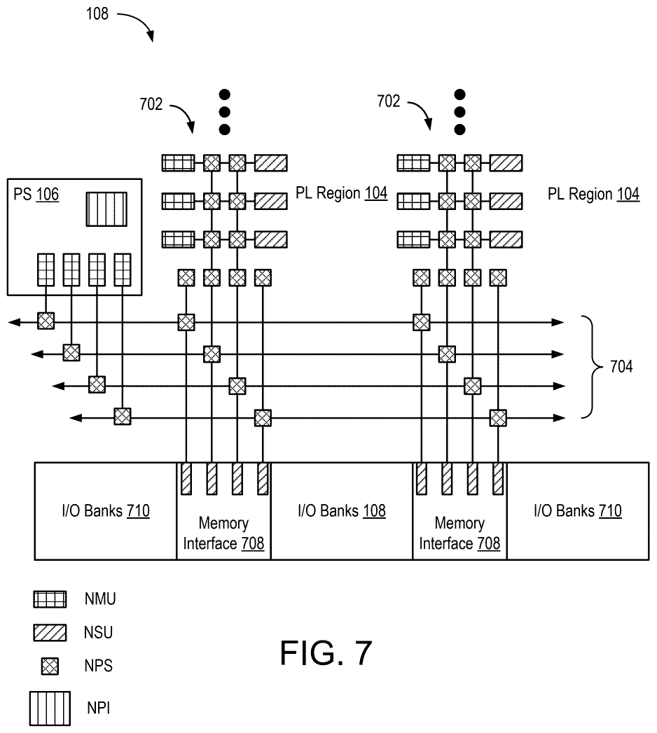

FIG. 7 is a block diagram depicting NoC 108 according to another example. In the example, NoC 108 includes vertical portions 702 (VNoC) and horizontal portion 704 (HNoC). Each VNoC 702 may be disposed between different regions of PL 204. The HNoC 704 may be disposed between the regions of PL 204 and the I/O banks 710 (e.g., I/O blocks and/or transceivers corresponding to hardwired circuit blocks 212). NoC 108 may be connected to memory interfaces 708 (e.g., other hardwired circuit blocks 212). PS 206 may be coupled to HNoC 704.

In the example, PS 106 includes a plurality of NMUs 502 coupled to HNoC 704. VNoC 702 includes both NMUs 502 and NSUs 504, which are disposed in PL 204. Memory interfaces 708 include NSUs 504 coupled to HNoC 704. Both HNoC 704 and VNoC 702 include NPSs 506 connected by routing 508. In VNoC 702, routing 508 extends vertically. In HNoC 704, routing 508 extends horizontally. In each of VNoC 702, each NMU 502 is coupled to an NPS 506. Likewise, each NSU 504 is coupled to an NPS 506. NPSs 506 are coupled to each other to form a matrix of switches. Some NPSs 506 in each VNoC 702 are coupled to other NPSs 506 in HNoC 704.

Although only a single HNoC 704 is shown, in other examples, NoC 108 can include more than one HNoC 704. In addition, while two VNoCs 702 are shown, NoC 108 can include more than two VNoCs 702. Although memory interfaces 708 are shown by way of example, it is to be understood that other circuit blocks can couple to NoC 108 in place of, or in addition to, the memory interfaces 708.

Referring to FIG. 3, NoC section 308 may store the locations of the NMUs 502 and the locations of the NSUs 504 used by circuit design 110. Similar to the example of FIG. 4, the name of each logical component of circuit design 110 that is assigned to an NMU 502 and/or an NSU 504 (e.g., an interface circuit whether a master or slave) may be stored in NoC section 308 along with a location of the site to which that logical component is placed or assigned. Thus, the entry and exit points for different nets/signal paths that traverse through NoC 108 may be stored and reused in light incremental flow 104.

FIGS. 8 and 9 are block diagrams illustrating certain operative features of clocking circuitry of IC 160 that may be captured as guide information within clocking section 310 of guide file 132 in accordance with one or more implementations of the disclosed technology.

FIG. 8 is a block diagram illustrating example clocking sites of IC 160. In the example of FIG. 8, the clocking sites illustrated correspond to primitives available on IC 160 that are used to implement the clocking network for circuit design 110. In the example, the following clocking primitives are illustrated, phase locked loops (PLLs) such as XPLLs and DPLLs, Mixed-Mode Clock Managers (MMCMs), clock buffers corresponding to PS 206 (BUFG_PS), clock buffers corresponding to PL 204 (BUFG_FABRIC), clock buffers corresponding to I/O blocks (BUFG_GT), and various other clock buffers (BUFGCE, BUFGCTRL, BUFGCE_DIV).

Clocking section 310 is capable of storing locations for each of the logical clocking components assigned to clocking primitives illustrated in FIG. 8. For example, clocking section 310 may store locations of the clocking primitives used by circuit design 110 as placed. The name of each logical component of circuit design 110 that is assigned to a clock component illustrated in FIG. 8 may be stored along with a location of the site (e.g., clocking primitive) to which the logical component is assigned. Thus, the clocking network may be stored in the form of the clocking primitive locations used and, as such, reused.

FIG. 9 is a block diagram illustrating an example clock expansion window for circuit design 110 as placed and routed. In the example of FIG. 9, clock expansion window 902 is illustrated. Clock expansion window 902 encompasses clock root 904 (e.g., a primitive of the target IC). A clock signal drives clock root 904 through clock buffer 906 (e.g., a primitive of the target IC). The clock signal is conveyed from clock buffer 906 along a selected one of 24 available tracks of a clock routing line 908 and a selected one of 24 available tracks of clock routing line 910. From clock root 904, the clock signal may be distributed to loads within clock expansion window 902 by way of a selected track of one or more clock distribution lines 912.

Clocking section 310 is capable of storing the logical component of circuit design 110 placed at clock root 904 and the location of clock root 904. Clocking section 310 is also capable of storing the logical component of circuit design 110 placed at clock buffer 906 and a clock region 914 in which the logical component is placed (as opposed to storing the location of clock buffer 906 itself). Further, information such as the size, e.g., the boundary, of clock expansion window 902 may be stored along with the particular tracks of clock routing lines 908 and 910 and the particular track(s) of clock distribution lines 912 used for the clock net.

For purposes of illustration, an example of a deterministic change includes adding one or more new loads to a net when the newly added load(s) fit into a same or existing clock expansion window that includes the existing loads. Another example of a deterministic change includes adding one or more new loads to a net when the newly added load(s) fit into a same SLR (e.g., die) as the existing loads.

By storing the information illustrated in FIG. 9, the skew of clock signals distributed to loads of the various clock domains of circuit design 110 may be held relatively constant from reference implementation flow 102 to light incremental flow 104. With reference to clock buffer 906, by storing clock region 914 (e.g., a particular region of IC 160 that includes clock buffer 906), placement 122 in light incremental flow 104 is given flexibility in choosing a particular site within that clock region which may differ from the site selected in reference implementation flow 102. The site selected, however, still will be within the clock region specified by clocking section 310 thereby providing flexibility while ensuring stability.

Within this disclosure, the term “clock expansion window” refers to a bounding box that is drawn around, or that encompasses, each component that is clocked by a given clock signal. In the example, clock expansion windows are drawn along the boundaries of clock regions. Clock expansion window 902, for example, will include each clock load (e.g., circuit component) that is clocked by the clock signal illustrated in FIG. 9. In the example, each of the clock buffers noted drives a track of a clock routing line (e.g., one of the 24 tracks of clock routing lines 908, 910). Each track of a clock routing line is a separate clock line capable of carrying or conveying a different clock signal.

Clock distribution lines also include a plurality of tracks. Each track of a clock distribution line 912 is capable of carrying or conveying a different clock signal. The particular tracks of clock distribution lines convey clock signals to clock loads. A clock load is a component that is clocked by a given clock signal. Thus, the guide information within clocking section 310 may specify the particular tracks used for each of the clock routing lines and/or clock distribution lines used to route each of the clock signals of circuit design 110.

In general, clock routing lines may traverse different regions of IC 160 to a particular or selected point at which a clock signal may be conveyed from a track of the clock routing line to a track of a clock distribution line. A clock routing line (e.g., any of the tracks thereof) is configured to route a clock signal from a clock buffer to a central location or point from which the clock routing line connects to a track of a clock distribution line that connects to the clock loads. The clock signal may be conveyed from a track of a clock routing line to a track of a clock distribution line to the particular components clocked by the respective clock signal. Clock root 904 is the primitive or junction point between a track of a clock routing line (908, 910) and a track of a clock distribution line (912).

For purposes of illustration, Example 1 illustrates an example of a portion of guide information that may be stored in clocking section 310 of guide file 132. In the example, particular logical component names are specified as well as location information. A PLL, for example, may be specified as a PLL as part of the system clock within a clock region at X13Y0 in the target IC.

### Example 1

```
. . .
“clock management”: [
  “MMCM”: ( },
  “PLL”: (
    “phypcs_top/SYSCLK”: {
      “DPLL_X13Y0”,
      “DPLL”
    ]
  },
  “GT”: (
“phypcs_top/DN_PHY_PIE8[0].PIPE128_VP.phy_dn/X4.phy/
gt_quad_0/inst/quat_inst”: [
    “GTYP_QUAD_X1Y0”,
    “GTYP_QUAD”
  ],
“phypcs_top/DN_PHY_PIE8[1].PIPE128_VP.phy_dn/X4.phy/
gt_quad_0/inst/quad_inst”: [
“phypcs_top/UP_PHY_VERSAL.phy_up/X4.phy/gt_quad_0/
inst/quad_inst”: [
  )
),
“Clock Ports” : (
  “dn0_refclk_n”: [
    “GTYP_REFCLK_X1Y0”,
    “GTYP_REFCLKN”
  ]
. . .
```

Example 2 illustrates another example portion of guide information that may be stored in clocking section 310 of guide file 132. In Example 2, clock buffer guide information is specified for the target IC.

### Example 2

```
“Clock Buffer”: {
“i_mrmac_0_cips_wrapper/mrmac_0_cips_i/versal_cips_0/inst/
pspmc_0/inst/pl10_ref_clk”: {
  “buffer_name”: “xxxxx/buffer_pl1_clk_0.PL_CLK_0_BUFG”,
  “clock_root”: “X5Y4”
  “cew”: “CLOCKREGION_X1Y1:CLOCKREGION_X9Y5”
  “clock_region”: “X1Y1”
  “clock_track”: “23”
},
```

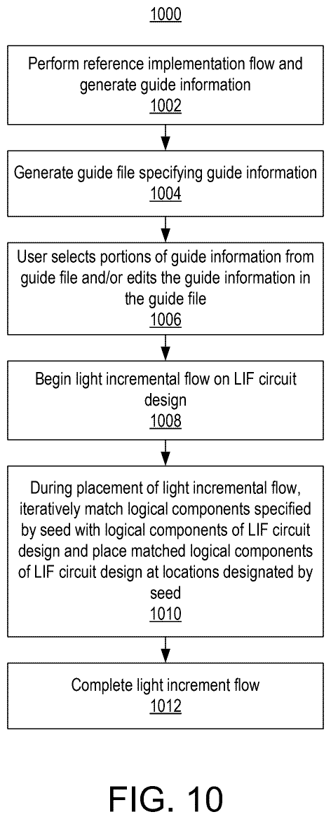

FIG. 10 illustrates an example method 1000 of operation for a data processing system (e.g., system) executing framework 100 of FIG. 1. An example of a data processing system that is suitable for executing framework 100 is described in connection with the example of FIG. 11.

In block 1002, the system performs reference implementation flow 102 on circuit design 110 and, in doing so, generates guide information. In block 1004, the system generates guide file 132 specifying the guide information. As noted, guide file 132 may specify the guide information in a human readable form, e.g., text. Guide file 132 may be specified as a JSON file. It should be appreciated, however, that guide file 132 may be specified in other text-based and/or human readable and editable formats. As another example, guide file 132 may be specified as an Extensible Markup Language (XML) document, though an XML document implementation may be larger and/or more complex than a JSON file.

In block 1006, a user may optionally select one or more portions of the guide information or the entirety of the guide information from guide file 132 for use as seed 134. Also, as part of block 1006, the user may optionally edit the guide information within guide file 132 so that seed 134 includes any user-specified edits and/or modifications. In one or more examples, the user may select particular portions of guide file 132 using a user interface (e.g., a graphical user interface) that allows the user to select each particular section of guide file 132 that is desired for use as seed 134. The user interface may be generated by guide information import 140. In other examples, the user may simply open guide file 132 and directly edit content therein by adding constraints, deleting constraints, or modifying existing constraints. Further, as discussed, the user may create different versions of guide file 132.

In block 1008, the system may begin light incremental flow on LIF circuit design 112. In block 1010, during operation of placement 122 of light incremental flow 104, the system is capable of restoring logical components of LIT circuit design 112 to sites and/or locations specified by seed 134. For example, as part of block 1008, the system is capable of iteratively matching each logical component specified by seed 134 with a logical component of LIF circuit design 112 and placing the matched logical component of LIF circuit design 112 at the location or in the region designated by seed 134. Any logical components of LIF circuit design 112 for which no placement information is found in seed 134 may be omitted from the process and placed as per usual operation of placement 122 subsequent to the iterative process to re-used the placement information from seed 134.

In block 1012, the system is capable of completing the light incremental flow. For example, placement 122 may complete placement with locations being reused as described. Routing 124 may route the placed version of LIF circuit design 112. As discussed, configuration data may be generated for the placed and routed LIF circuit design 112 such that the LIF circuit design may be physically realized in the target IC by loading the configuration data into the target IC. Further, as discussed, light incremental flow 104 is capable of generating a report that specifies the reusage of locations for logical components of LIF circuit design 112.

FIG. 11 illustrates an example of a data processing system 1100. As used herein, “data processing system” refers to one or more hardware systems capable of processing data. Each hardware system may include one or more hardware processors and memory.

Data processing system 1100 includes a hardware processor 1102. Hardware processor 1102 may be implemented as one or more hardware processors. Hardware processor 1102 may be implemented as one or more circuits capable of executing computer-readable program instructions (program instructions). The circuit(s) may comprise integrated circuits (ICs) or may be embedded within an IC. In one or more examples, hardware processor 1102 may be embodied as a central processing unit (CPU). Hardware processor 1102 may include one or more cores, for example, where each core is capable of executing computer-readable program instructions. Hardware processor 1102 may be implemented using any of a variety of architectures such as, for example, a complex instruction set computer architecture (CISC), a reduced instruction set computer architecture (RISC), a vector processing architecture, or other known architectures. For example, a hardware processor may be implemented using an x86 architecture (e.g., IA-32, IA-64), a Power Architecture, as an ARM processor, or the like.

Data processing system 1100 can include memory 1104. Memory 1104 may be embodied as one or more computer-readable storage mediums. Memory 1104 may include a volatile memory 1106 and a non-volatile memory 1108. Volatile memory 1106 may be embodied as random-access memory (RAM) and may include cache memory. Volatile memory 1106 may be referred to as “runtime memory.” Non-volatile memory 1108 may include a non-volatile magnetic medium and/or a solid-state medium (typically called a “hard drive”). Non-volatile memory 1108 also may include one or more disk drives capable of reading from and writing to various types of removable, non-volatile mediums such as a removable, non-volatile magnetic disk (e.g., a “floppy disk”) and/or a removable, non-volatile optical disk such as a CD-ROM, DVD-ROM or other optical media.

Memory 1104 is capable of storing program instructions and/or data such that hardware processor 1102 is capable of executing the program instructions to perform one or more operations as described within this disclosure. For example, the program instructions can include an operating system, one or more application programs, other program code, and program data. Memory 1104, for example, may store framework 100 and/or portions thereof (e.g., one or both of the illustrated flows). Hardware processor 1102, in executing the computer-readable program instructions, is capable of performing the various operations described herein that are attributable to a computer. In one or more examples, the program instructions may be embodied as an EDA tool that when executed, causes the hardware processor 1102 to perform one or more of the example implementation flows described herein on a circuit design.

Data processing system 1100 may include one or more Input/Output (I/O) interfaces 1110. I/O interface(s) 1110 allow data processing system 1100 to communicate with one or more external devices and/or communicate over one or more networks such as a local area network (LAN), a wide area network (WAN), and/or a public network (e.g., the Internet). Examples of I/O interfaces 1110 may include, but are not limited to, network cards, modems, network adapters (wired and/or wireless), hardware controllers, etc. Examples of external devices also may include devices that allow a user to interact with data processing system 1100 (e.g., a display, a keyboard, and/or a pointing device) and/or other devices such as accelerator card.

Bus 1112 represents one or more of any of a variety of communication bus structures. By way of example, and not limitation, bus 1112 may be implemented as a Peripheral Component Interconnect Express (PCIe) bus. Bus 1112 couples to each of hardware processor 1102, memory 1104, and I/O interface(s) 1110 through respective interface circuitry thereby allowing the devices to communicate. Bus 1112 may represent a plurality of buses that may be interconnected and/or hierarchically organized.

Data processing system 1100 is only one example implementation. Data processing system 1100 can be practiced as a standalone device (e.g., as a user computing device or a server, as a bare metal server), in a cluster (e.g., two or more interconnected computers), or in a distributed cloud computing environment (e.g., as a cloud computing node) where tasks are performed by remote processing devices that are linked through a communications network. In a distributed cloud computing environment, program modules may be located in both local and remote computer system storage media including memory storage devices.

As used herein, the term “cloud computing” refers to a computing model that facilitates convenient, on-demand network access to a shared pool of configurable computing resources such as networks, servers, storage, applications, ICs (e.g., programmable ICs) and/or services. These computing resources may be rapidly provisioned and released with minimal management effort or service provider interaction. Cloud computing promotes availability and may be characterized by on-demand self-service, broad network access, resource pooling, rapid elasticity, and measured service.

The example of FIG. 11 is not intended to suggest any limitation as to the scope of use or functionality of example implementations described herein. Data processing system 1100 is an example of computer hardware that is capable of performing the various operations described within this disclosure. In this regard, data processing system 1100 may include fewer components than shown or additional components not illustrated in FIG. 11 depending upon the particular type of device and/or system that is implemented. The particular operating system and/or application(s) included may vary according to device and/or system type as may the types of I/O devices included. Further, one or more of the illustrative components may be incorporated into, or otherwise form a portion of, another component. For example, a processor may include at least some memory.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the term “computer-readable storage medium” means a storage medium that contains or stores program instructions for use by or in connection with an instruction execution system, apparatus, or device. As defined herein, a “computer-readable storage medium” is not a transitory, propagating signal per se. The various forms of memory, as described herein, are examples of a computer-readable storage medium or two or more computer-readable storage mediums. A non-exhaustive list of examples of a computer-readable storage medium include an electronic storage device, a magnetic storage device, an optical storage device, an electromagnetic storage device, a semiconductor storage device, or any suitable combination of the foregoing. A non-exhaustive list of more specific examples of a computer-readable storage medium may include: a portable computer diskette, a hard disk, a RAM, a read-only memory (ROM), an erasable programmable read-only memory (EPROM or Flash memory), an electronically erasable programmable read-only memory (EEPROM), a static random-access memory (SRAM), a double-data rate synchronous dynamic RAM memory (DDR SDRAM or “DDR”), a portable compact disc read-only memory (CD-ROM), a digital versatile disk (DVD), a memory stick, a floppy disk, or the like.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “user” refers to a human being.

As defined herein, the term “hardware processor” means at least one hardware circuit. The hardware circuit may be configured to carry out instructions contained in program code. The hardware circuit may be an integrated circuit. Examples of a hardware processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a controller, and a Graphics Processing Unit (GPU).

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc. may be used herein to describe various elements. These elements should not be limited by these terms, as these terms are only used to distinguish one element from another unless stated otherwise or the context clearly indicates otherwise.

A computer program product may include a computer-readable storage medium (or mediums) having computer-readable program instructions thereon for causing a processor to carry out aspects of the implementations described herein. Within this disclosure, the terms “program code,” “program instructions,” and “computer-readable program instructions” are used interchangeably. Computer-readable program instructions described herein may be downloaded to respective computing/processing devices from a computer-readable storage medium or to an external computer or external storage device via a network, for example, the Internet, a LAN, a WAN and/or a wireless network. The network may include copper transmission cables, optical transmission fibers, wireless transmission, routers, firewalls, switches, gateway computers and/or edge devices including edge servers. A network adapter card or network interface in each computing/processing device receives program instructions from the network and forwards the computer-readable program instructions for storage in a computer-readable storage medium within the respective computing/processing device.

Program instructions for carrying out operations for the implementations described herein may be assembler instructions, instruction-set-architecture (ISA) instructions, machine instructions, machine dependent instructions, microcode, firmware instructions, or either source code or object code written in any combination of one or more programming languages, including an object-oriented programming language and/or procedural programming languages. Program instructions may include state-setting data. The program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a LAN or a WAN, or the connection may be made to an external computer (for example, through the Internet using an Internet Service Provider). In some cases, electronic circuitry including, for example, programmable logic circuitry, an FPGA, or a PLA may execute the program instructions by utilizing state information of the program instructions to personalize the electronic circuitry, in order to perform aspects of the implementations described herein.

Certain aspects of the implementations are described herein with reference to flowchart illustrations and/or block diagrams of methods, apparatus (systems), and computer program products. It will be understood that each block of the flowchart illustrations and/or block diagrams, and combinations of blocks in the flowchart illustrations and/or block diagrams, may be implemented by program instructions, e.g., program code.

These program instructions may be provided to a processor of a computer, special-purpose computer, or other programmable data processing apparatus to produce a machine, such that the program instructions, which execute via the processor of the computer or other programmable data processing apparatus, create means for implementing the functions/acts specified in the flowchart and/or block diagram block or blocks. These program instructions may also be stored in a computer-readable storage medium that can direct a computer, a programmable data processing apparatus, and/or other devices to function in a particular manner, such that the computer-readable storage medium having program instructions stored therein comprises an article of manufacture including program instructions which implement aspects of the operations specified in the flowchart and/or block diagram block or blocks.

The program instructions may also be loaded onto a computer, other programmable data processing apparatus, or other device to cause a series of operations to be performed on the computer, other programmable apparatus or other device to produce a computer implemented process, such that the program instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various aspects of the implementations. In this regard, each block in the flowchart or block diagrams may represent a module, segment, or portion of instructions, which comprises one or more program instructions for implementing the specified operations.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and program instructions.

The descriptions of the various implementations of the disclosed technology have been presented for purposes of illustration, but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A method, comprising:
receiving guide information including placement information for a circuit design from a prior implementation flow;
performing a light incremental flow on the circuit design using the guide information;
wherein the light incremental flow generates a placed and routed circuit design that re-uses at least a portion of the placement information from the prior implementation flow.

2. The method of claim 1, wherein the placement information specifies location information for one or more logical components of the circuit design placed at a hard macro.

3. The method of claim 1, wherein the placement information specifies location information for one or more logical components of the circuit design placed at an input/output (I/O) block.

4. The method of claim 1, wherein the placement information specifies location information for one or more logical components of the circuit design placed at a Network-on-Chip (NoC) interface.

5. The method of claim 1, wherein the placement information specifies location information for one or more logical components of the circuit design placed at a clocking component.

6. The method of claim 1, wherein the placement information specifies location information for one or more logical components of the circuit design coupled to an inter-die connection.

7. The method of claim 1, further comprising:
iteratively matching logical components of the circuit design during the light incremental flow with logical components specified in the guide information and using the placement information from the guide information for the matched logical components of the circuit design during placement of the light incremental flow.

8. The method of claim 1, wherein the guide information defines a plurality of constraints specified as human readable data in a file.

9. The method of claim 8, further comprising at least one of:
using only a subset of the guide information as selected by a user during the light incremental flow; or
using the at least a portion of the guide information as modified by a user during the light incremental flow.

10. The method of claim 1, wherein:
the circuit design as processed through the light incremental flow is a modified version of the circuit design processed through the prior implementation flow; or
a different version of a computer-based implementation tool performs the light incremental flow than the prior implementation flow.

11. A system, comprising:
a hardware processor;
one or more computer-readable storage media storing program instructions to cause the hardware processor to perform operations comprising:
receiving guide information including placement information for a circuit design from a prior implementation flow;
performing a light incremental flow on the circuit design using the guide information;
wherein the light incremental flow generates a placed and routed circuit design that re-uses at least a portion of the placement information from the prior implementation flow.

12. The system of claim 11, wherein the placement information specifies location information for one or more logical components of the circuit design placed at a hard macro.

13. The system of claim 11, wherein the placement information specifies location information for one or more logical components of the circuit design placed at an input/output (I/O) block.

14. The system of claim 11, wherein the placement information specifies location information for one or more logical components of the circuit design placed at a Network-on-Chip (NoC) interface.

15. The system of claim 11, wherein the placement information specifies location information for one or more logical components of the circuit design placed at a clocking component.

16. The system of claim 11, wherein the placement information specifies location information for one or more logical components of the circuit design coupled to an inter-die connection.

17. The system of claim 11, wherein the program instructions cause the hardware processor to perform operations further comprising:
iteratively matching logical components of the circuit design during the light incremental flow with logical components specified in the guide information and using the placement information from the guide information for the matched logical components of the circuit design during placement of the light incremental flow.

18. The system of claim 11, wherein the guide information defines a plurality of constraints specified as human readable data in a file.

19. The system of claim 11, wherein the program instructions cause the hardware processor to perform operations further comprising at least one of:
use only a subset of the guide information as selected by a user during the light incremental flow; or
use the at least a portion of the guide information as modified by a user during the light incremental flow.

20. A computer program product comprising:
one or more computer-readable storage mediums; and
program instructions stored on the one or more computer-readable storage mediums to perform operations comprising:
receiving guide information including placement information for a circuit design from a prior implementation flow;
performing a light incremental flow on the circuit design using the guide information;
wherein the light incremental flow generates a placed and routed circuit design that re-uses at least a portion of the placement information from the prior implementation flow.
